(19) United States
(12) Patent Application Publication
(10) Pub. No.: US 2026/0144149 A1
(43) Pub. Date: May 21, 2026

(54) SEMICONDUCTOR PACKAGE

(71) Applicant: SAMSUNG ELECTRONICS CO., LTD., Suwon-si, Gyeonggi-do (KR)

(72) Inventor: Hyunsoo CHUNG, Suwon-si (KR)

(73) Assignee: SAMSUNG ELECTRONICS CO., LTD., Suwon-si, Gyeonggi-do (KR)

(21) Appl. No.: 19/239,205

(22) Filed: Jun. 16, 2025

(30) Foreign Application Priority Data
Nov. 20, 2024 (KR) 10-2024-0166543

(51) Int. Cl. H01L 25/065; H01L 21/56; H01L 23/00; H01L 23/31; H01L 23/367; H01L 23/48; H01L 23/498; H01L 23/522; H01L 23/538; H01L 25/00; H10B 80/00

(52) U.S. Cl. CPC H10W 90/00; H10B 80/00; H10W 20/20; H10W 20/42; H10W 70/611; H10W 70/65; H10W 90/401; H10W 40/228; H10W 74/016; H10W 74/10; H10W 74/114; H10W 80/312; H10W 80/327; H10W 90/724; H10W 90/792

(57) ABSTRACT

A semiconductor package includes a first chip, a second chip, a third chip, a redistribution layer and a through via. The first chip includes a first substrate layer above a power distribution layer and a first device layer disposed over the first substrate layer. The second chip includes a second device layer disposed over the first chip to face the first device layer, and a second substrate layer disposed over the second device layer. The third chip is disposed over the first chip, farther from the first chip than the second chip in a first direction. The redistribution layer is disposed between the second chip and the third chip, and electrically connected to the third chip. The through via is spaced apart from the second chip, disposed between the redistribution layer and the first chip, and electrically connecting the redistribution layer and the first chip.

### CROSS-REFERENCE TO RELATED APPLICATIONS

This application claims the benefit of Korean Patent Application No. 10-2024-0166543, filed on Nov. 20, 2024, in the Korean Intellectual Property Office, the disclosure of which is incorporated herein by reference in its entirety.

### BACKGROUND

### 1. Field of the Invention

Example embodiments of the present disclosure relate to a semiconductor package.

### 2. Description of the Related Art

Due to the development of the electronics industry, the demand for high-performance, high-speed, and miniaturized electronic components is increasing. In response to this trend, a method of stacking and mounting multiple semiconductor chips in a single package wiring structure or stacking packages on top of packages can be used. For example, a package-in-package (PIP) type semiconductor package or a package-on-package (POP) type semiconductor package can be used.

Meanwhile, used are vertical wiring structures in which as semiconductor packages become more highly integrated, semiconductor chips are stacked vertically and the semiconductor pins are electrically connected.

### SUMMARY

An aspect provides a semiconductor package in which power supply to chips is smooth.

An aspect provides a semiconductor package by which the latency in signal transmission between chips is reduced.

An aspect provides a semiconductor package of which heat dissipation efficiency is improved.

The technical tasks to be achieved by the present example embodiments are not limited to the technical tasks described above, and other technical tasks may be inferred from the following example embodiments by those skilled in the art.

According to an aspect, there is provided a semiconductor package including a first chip comprising a first substrate layer disposed above a power distribution layer, and a first device layer that includes a first semiconductor device and is disposed over the first substrate layer, a second chip comprising a second device layer that includes a second semiconductor device and is disposed over the first chip to face the first device layer, and a second substrate layer disposed over the second device layer, a third chip disposed over the first chip, and disposed farther from the first chip than the second chip in a first direction, a redistribution layer disposed between the second chip and the third chip, and electrically connected to the third chip, and a through via spaced apart from the second chip, disposed between the redistribution layer and the first chip, and electrically connecting the redistribution layer and the first chip.

According to an aspect, there is provided a semiconductor package including a first chip comprising a first substrate layer disposed above a power distribution layer, and a first device layer that includes a first semiconductor device and is disposed over the first substrate layer, a second chip comprising a second substrate layer and a second device layer that includes a second semiconductor device and is disposed over the first chip, a redistribution layer disposed over the second chip, and spaced apart from the first chip, and a through via spaced apart from the second chip, disposed between the redistribution layer and the first chip, and electrically connecting the redistribution layer and the first chip.

According to an aspect, there is provided a method of manufacturing a semiconductor package. The method includes: disposing a power distribution layer over a first side of a first chip, wherein the first chip comprises a first device layer including a first semiconductor device; disposing a second chip over a second side of the first chip, wherein the second chip comprises a second device layer including a second semiconductor device, and the second device layer faces the first device layer; disposing a through via over the first chip at a lateral side of the second chip; disposing a redistribution layer over the through via, wherein the redistribution layer is electrically connected to the through via; and disposing a third chip over the redistribution layer, wherein the third chip is electrically connected to the redistribution layer.

Additional aspects of example embodiments will be set forth in part in the description that follows and, in part, will be apparent from the description, or may be learned by practice of the disclosure.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a drawing illustrating a cross-section of a semiconductor package according to an example embodiment;

FIG. 2 to FIG. 12 are drawings explaining a manufacturing process of a semiconductor package according to an example embodiment; and

FIG. 13 is a drawing illustrating a cross-section of a semiconductor package according to an example embodiment.

### DETAILED DESCRIPTION

Prior to the detailed description of the present disclosure, terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings are only the most preferred embodiments of the present disclosure, and do not necessarily represent the entire technical idea of the present disclosure. Accordingly, at the time of filing the present disclosure, there may be various equivalents and modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

In the present disclosure, singular expressions include plural expressions unless the context clearly indicates otherwise. Further, terms “first,” “second” and so on may be used to describe various components. However, the components are not limited by the terms, and the terms may be used for the purpose of distinguishing one component from another. Within the scope of the technical idea of the present disclosure, the first component may be named as the second component. Similarly, the second component may also be named the first component. Further, the shape and size of components may be exaggerated to emphasize clear explanation.

Further, in the following description, expressions such as an upper side, top, a lower side, bottom, a side, front and a back side are expressed based on the direction shown in the drawing. If the direction of the object changes, it may be expressed differently. The shapes and sizes of elements in the drawings may be exaggerated for clearer explanation.

Hereinafter, example embodiments according to the technical idea of the present disclosure will be described with reference to the attached drawings.

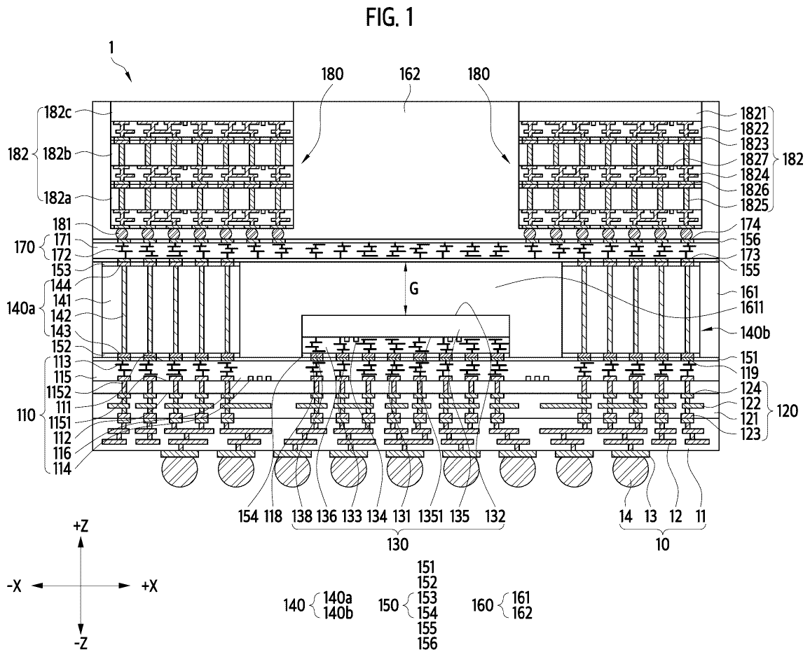

FIG. 1 is a drawing for explaining a semiconductor package 1 according to some embodiments.

According to some example embodiments, the semiconductor package 1 may include a package substrate 10, a first chip 110, a power distribution layer 120, a second chip 130, a bridge structure 140, a bonding layer 150, a molding layer 160, a redistribution layer 170 and a chip stack 180.

According to some example embodiments, the package substrate 10 may be a wiring structure for a package. For example, the package substrate 10 may be a printed circuit board (PCB), a ceramic substrate, or an interposer. Alternatively, it is apparent that the package substrate 10 may be a wiring structure for a wafer level package (WLP) manufactured at the wafer level.

According to some example embodiments, the package substrate 10 may function as a redistribution layer. For example, the package substrate 10 may be a front redistribution layer (FRDL) of a fan-out package.

In some example embodiments, the package substrate 10 may be a glass substrate, a ceramic substrate or a plastic substrate, but the package substrate 10 is not limited thereto. For example, the package substrate 10 may include a resin impregnated in a core material such as glass fiber (or, glass cloth and glass fabric) together with an inorganic filler. For example, prepreg, an Ajinomoto build-up film (ABF), FR-4, or Bismaleimide Triazine (BT) may be included.

According to some example embodiments, the package substrate 10 may include a redistribution insulating film 11 and a redistribution structure 12.

According to some example embodiments, when the package substrate 10 is a PCB, the redistribution insulating film 11 may be made of at least one material selected from phenol resin, epoxy resin and polyimide. The package substrate 10 may include at least one material selected from tetrafunctional epoxy, polyphenylene ether, epoxy/polyphenylene oxide, bismaleimide triazine (BT), thermount, cyanate ester, and liquid crystal polymer.

In some example embodiments, the redistribution insulating film 11 may include photoimageable dielectric. For example, the redistribution insulating film 11 may include a photoimageable polymer. The photoimageable polymer may be formed from at least one of, for example, a photoimageable polyimide, a polybenzoxazole, a phenol-based polymer and a benzocyclobutene-based polymer. In another example embodiment, the redistribution insulating film 11 may be formed of a silicon oxide film, a silicon nitride film or a silicon oxynitride film.

According to some example embodiments, the redistribution insulating film 11 may include a plurality of insulating films that are laminated. Each of the plurality of insulating films may surround the wiring pattern and the wiring via of the redistribution structure 12 described later.

Even though not illustrated, the surface of the redistribution insulating film 11 may be covered with a solder resist. For example, a passivation film may be formed on the surface of the redistribution insulating film 11. The passivation film formed on the surface of the redistribution insulating film 11 may protect the redistribution structure 12 and other structures from external impact or moisture. The passivation film may include a solder resist. However, the technical idea of the present disclosure is not limited thereto.

According to some example embodiments, the redistribution structure 12 may be arranged within the redistribution insulating film 11. The redistribution structure 12 may contain wiring patterns and wiring vias that connect each wiring pattern. For example, the redistribution structure 12 may be a multilayer structure in which two or more wiring patterns or two or more wiring vias are alternately stacked. The wiring pattern may be a part of a horizontal connection between conductive components, and the wiring via may be a part for vertical connection between conductive components. For example, the wiring pattern may be extended in the third direction (+X). The wiring vias may connect wiring patterns that are separated in the first direction (+Z). Here, the first direction (+Z) may refer to a direction perpendicular to the surface of the package substrate 10.

In some example embodiments, the redistribution structure 12 may include a conductive material. For example, the redistribution structure 12 may include copper (Cu), aluminum (Al), silver (Ag), tin (Sn), gold (Au), nickel (Ni), lead (Pb), titanium (Ti), or alloys thereof. However, the redistribution structure 12 is not limited thereto.

According to some example embodiments, an external connection terminal 14 may be formed on the lower surface of the package substrate 10. The external connection terminal 14 may be disposed on an external connection pad 13. The external connection terminal 14 may make contact with the external connection pad 13. For example, the external connection terminal 14 may include a solder ball or a solder bump. In another example embodiment, the external connection terminal 14 may include micro bumps. The external connection terminal 14 may be, but is not limited to, a spherical or elliptical shape. The number, spacing, arrangement, shape and so on of the external connection terminal 14 are not limited to those illustrated, and it is apparent that the number, spacing, arrangement, shape and so on of the external connection terminal 14 may be various according to example embodiments. The external connection terminal 14 may include, for example, tin (Sn), indium (In), bismuth (Bi), antimony (Sb), copper (Cu), silver (Ag), zinc (Zn), lead (Pb), and combinations thereof, but the external connection terminal 14 is not limited thereto.

According to some example embodiments, the external connection terminal 14 may electrically connect the redistribution structure 12 to an external device. Accordingly, the external connection terminal 14 may provide electrical signals to the redistribution structure 12, or provide electrical signals from the redistribution structure 12 to an external device.

According to some example embodiments, a chip (for example, the first chip 110, the second chip 130 and a third chip 182) may be an integrated circuit (IC) with hundreds to millions of semiconductor devices integrated into a single chip. For example, the chips (the first chip 110, the second chip 130 and the third chip 182) may be volatile memory chips such as dynamic random access memory (DRAM) or static random access memory (SRAM). Alternatively, the chips (the first chip 110, the second chip 130 and the third chip 182) may be non-volatile memory chips such as flash memory, phase-change RAM (PRAM), magnetoresistive RAM (MRAM), ferroelectricRAM (FeRAM) and resistive RAM (RRAM). In another example embodiment, the chips (the first chip 110, the second chip 130 and the third chip 182) may include logic chips. The chips (the first chip 110, the second chip 130 and the third chip 182) may be application processors (APs) such as central processing unit (CPU), graphic processing unit (GPU), field-programmable gate array (FPGA), digital signal processors, cryptographic processors, microprocessors, and microcontrollers. However, the chips are not limited thereto.

According to some example embodiments, the substrate layer (for example, a first substrate layer 115, a second substrate layer 135 and a third substrate layer 1821) may be bulk silicon or silicon-on-insulator (SOI). In another example embodiment, the substrate layers (the first substrate layer 115, the second substrate layer 135 and the third substrate layer 1821) may be a silicon substrate. In another example embodiment, the substrate layer (the first substrate layer 115, the second substrate layer 135 and the third substrate layer 1821) may include silicon germanium, silicon germanium on insulator (SGOI), indium antimonide, lead telluride, indium arsenide, indium phosphide, gallium arsenide and/or gallium antimonide. However, the substrate layers are not limited thereto. The substrate layer (the first substrate layer 115, the second substrate layer 135 and the third substrate layer 1821) may include a conductive area, for example, a doped well or a doped structure. The substrate layers (the first substrate layer 115, the second substrate layer 135 and the third substrate layer 1821) may have various device isolation structures such as a shallow trench isolation (STI) structure.

According to some example embodiments, the device layer (for example, a first device layer 116, a second device layer 136 and a third device layer 1822) may be disposed on one side of the substrate layer (for example, the first substrate layer 115, the second substrate layer 135 and the third substrate layer 1821). The device layer (the first device layer 116, the second device layer 136 and the third device layer 1822) may include a plurality of semiconductor devices (for example, a first semiconductor device 114, a second semiconductor device 134 and a third semiconductor device 1827) that are of various types, and an insulating film between the layers. The plurality of semiconductor devices (the first semiconductor device 114, the second semiconductor device 134 and the third semiconductor device 1827) may include various microelectronic devices. For example, included may be metal-oxide-semiconductor field effect transistors (MOSFET), such as complementary metal-insulator-semiconductor (CMOS) transistors, system large scale integration (LSI) circuits, image sensors such as flash memory, DRAM, SRAM, EEPROM, PRAM, MRAM, RRAM, CMOS imaging sensors (CIS), micro-electro-mechanical systems (MEMS), active devices, and/or passive devices.

According to some example embodiments, the plurality of semiconductor devices (for example, the first semiconductor device 114, the second semiconductor device 134 and the third semiconductor device 1827) in a device layer (for example, the first device layer 116, the second device layer 136 and the third device layer 1822) may be electrically connected to a conductive area formed within a substrate layer (for example, the first substrate layer 115, the second substrate layer 135 and the third substrate layer 1821). The plurality of semiconductor devices (the first semiconductor device 114, the second semiconductor device 134 and the third semiconductor device 1827) of the device layer (the first device layer 116, the second device layer 136 and the third device layer 1822) may be electrically isolated from other neighboring plurality of semiconductor devices (the first semiconductor device 114, the second semiconductor device 134 and the third semiconductor device 1827) by insulating films.

According to some example embodiments, the device layer (for example, the first device layer 116, second device layer 136 and third device layer 1822) may include wiring electrically connecting at least two of the plurality of semiconductor devices (for example, first semiconductor device 114, second semiconductor device 134 and third semiconductor device 1827), or electrically connecting the plurality of semiconductor devices (the first semiconductor device 114, the second semiconductor device 134 and the third semiconductor device 1827) to a conductive area of the substrate layer (for example, first substrate layer 115, second substrate layer 135 and third substrate layer 1821). The wiring (the first wiring 113, the second wiring 133 and the third wiring 1824) may have a multilayer structure in which two or more metal wirings or two or more via plugs are alternately laminated. The wiring (the first wiring 113, the second wiring 133 and the third wiring 1824) may include a conductive material. For example, the wiring (the first wiring 113, the second wiring 133 and the third wiring 1824) may include copper (Cu), aluminum (Al), silver (Ag), tin (Sn), gold (Au), nickel (Ni), lead (Pb), titanium (Ti), or alloys thereof. However, the wiring is not limited thereto.

According to some example embodiments, the insulating layer may be formed on the device layer (for example, the first device layer 116, the second device layer 136 and the third device layer 1822) to protect the wiring (for example, the first wiring 113, the second wiring 133 and the third wiring 1824) and other structures within the device layers (the first device layer 116, the second device layer 136 and the third device layer 1822) from external impact or moisture.

According to some example embodiments, the semiconductor package 1 may include the first chip 110. The first chip 110 may be a logic chip. The first chip 110 may be disposed on the upper side of the package substrate 10. The first chip 110 may be spaced apart from the package substrate 10. The first chip 110 may be electrically connected to the package substrate 10.

According to some example embodiments, the first chip 110 may include a first frontside 111 and a first backside 112. The first frontside 111 may be positioned facing the first direction (+Z). The first backside 112 may be disposed facing the second direction (−Z), which is opposite to the first direction (+Z). The first backside 112 may be a side of the first chip 110 opposite to the first frontside 111. The first frontside 111 may be located further from the package substrate 10 than the first backside 112.

According to some example embodiments, the first chip 110 may include the first substrate layer 115. The first substrate layer 115 may include a non-conductive material (for example, silicon (Si)). The first substrate layer 115 may include the first backside 112. The first backside 112 may be a side of the first substrate layer 115 facing the package substrate 10. The first substrate layer 115 may include a first substrate surface 1151. The first substrate surface 1151 may be a side of the first substrate layer 115 opposite to the first backside 112. The first substrate surface 1151 may face the first device layer 116. The first substrate layer 115 may include a first conductive via 1152. The first conductive via 1152 may extend through the first substrate layer 115. The first conductive via 1152 may extend from the first backside 112 toward the first substrate surface 1151.

According to some example embodiments, the first chip 110 may include the first device layer 116. The first device layer 116 may include the first frontside 111. The first frontside 111 may be a side of the first device layer 116 facing opposite to the direction toward the first substrate layer 115.

According to some example embodiments, the first chip 110 may include the first semiconductor device 114. The first semiconductor device 114 may be disposed inside the first device layer 116. The first semiconductor device 114 may be disposed on the first substrate surface 1151.

According to some example embodiments, the first chip 110 may include the first wiring 113. The first wiring 113 may be disposed inside the first device layer 116. The first wiring 113 may be electrically connected to the first semiconductor device 114. The first wiring 113 may contain a conductive material, and transmit electrical signals generated from the first semiconductor device 114. The first wiring 113 may be extended towards the first frontside 111, and be connected to a first chip pad 118 or a bridge connection pad 119 located on the first frontside 111.

According to some example embodiments, the semiconductor package 1 may include the power distribution layer 120. The power distribution layer 120 may include a back side power delivery network (BSPDN). The power distribution layer 120 may supply power to chips in the semiconductor package 1 (for example, the first chip 110, the second chip 130 and the third chip 182).

According to some example embodiments, the power distribution layer 120 may be disposed between the package substrate 10 and the first chip 110. The power distribution layer 120 may face the first backside 112 of the first chip 110. The power distribution layer 120 may face the first substrate layer 115. The power distribution layer 120 may transmit power to the first semiconductor device 114 and the first wiring 113 through the first conductive via 1152 arranged inside the first substrate layer 115.

According to some example embodiments, the power distribution layer 120 may include a power wiring insulating film 121. The power wiring insulating film 121 may contain a non-conductive material. The power wiring insulating film 121 may surround a power wiring 122. The power distribution layer 120 may include the power wiring 122. The power wiring 122 may be configured to transmit a power signal.

According to some example embodiments, the power distribution layer 120 may include a first power wiring pad 123 and a second power wiring pad 124. The first power wiring pad 123 may electrically connect the power wiring 122 and the redistribution structure 12. The second power wiring pad 124 may electrically connect the power wiring 122 and the first conductive via 1152.

According to some example embodiments, the semiconductor package 1 may include the second chip 130. The second chip 130 may be a memory chip. For example, the second chip 130 may be a last level cache dynamic random access memory (LLC DRAM). The second chip 130 may be disposed on the upper side of the package substrate 10. The second chip 130 may be disposed on top of the first chip 110. The second chip 130 may be electrically connected to the first chip 110. The second chip 130 may receive power from the power distribution layer 120 through the first chip 110.

According to some example embodiments, the second chip 130 may include a second frontside 131 and a second backside 132. The second frontside 131 may be positioned facing the second direction (−Z). The second backside 132 may be positioned facing the first direction (+Z). The second backside 132 may be a side of the second chip 130 opposite to the second frontside 131. The second backside 132 may be located further from the first chip 110 than the second frontside 131.

According to some example embodiments, the second chip 130 may be arranged in order for the second frontside 131 to face the first chip 110. The second frontside 131 may face the first frontside 111. The second device layer 136 of the second chip 130 may face the first device layer 116 of the first chip 110.

According to some example embodiments, the second chip 130 may include the second substrate layer 135. The second substrate layer 135 may include a non-conductive material (for example, silicon (Si)). The second substrate layer 135 may include the second backside 132. The second substrate layer 135 may include a second substrate surface 1351. The second substrate surface 1351 may be a side of the second substrate layer 135 opposite to the second backside 132. The second substrate surface 1351 may face the second device layer 136.

According to some example embodiments, the second chip 130 may include the second device layer 136. The second device layer 136 may include the second frontside 131. The second frontside 131 may be a side of the second device layer 136 facing opposite to the direction facing the second substrate layer 135.

According to some example embodiments, the second chip 130 may include the second semiconductor device 134. The second semiconductor device 134 may be disposed within the second device layer 136. The second semiconductor device 134 may be disposed on the second substrate surface 1351.

According to some example embodiments, the second chip 130 may include the second wiring 133. The second wiring 133 may be disposed inside the second device layer 136. The second wiring 133 may be electrically connected to the second semiconductor device 134. The second wiring 133 may contain a conductive material, and transmit electrical signals generated from the second semiconductor device 134. The second wiring 133 may be extended towards the second frontside 131, and be connected to a second chip pad 138 located on the second frontside 131.

According to some example embodiments, the semiconductor package 1 may include the bridge structure 140. The bridge structure 140 may be disposed on the upper side of the package substrate 10. The bridge structure 140 may be disposed on the upper side of the first chip 110. The bridge structure 140 may be disposed on the lateral side (e.g., a peripheral side) of the second chip 130. The bridge structure 140 may be spaced from the lateral side of the second chip 130. The bridge structure 140 may include a first bridge structure 140a and a second bridge structure 140b spaced apart from each other with the second chip 130 therebetween. A plurality of bridge structures 140 may be disposed, and the number of the bridge structures140 is not limited to what is described above.

According to some example embodiments, the bridge structure 140 may include a bridge substrate 141 and a through via 142. The bridge substrate 141 may surround the through via 142. The bridge substrate 141 may include a non-conductive material. The through via 142 may contain a conductive material. The through via 142 may be extended in the first direction (+Z) from the first chip 110. The through via 142 may electrically connect the first chip 110 and the redistribution layer 170.

According to some example embodiments, the bridge structure 140 may include a first bridge pad 143 and a second bridge pad 144. The first bridge pad 143 may electrically connect the through via 142 and the first chip 110. The first bridge pad 143 may be contacted with the bridge connection pad 119. The second bridge pad 144 may electrically connect the through via 142 and the redistribution layer 170. The second bridge pad 144 may be contacted with a first redistribution pad 173.

According to some example embodiments, the semiconductor package 1 may include the bonding layer 150. The bonding layer 150 may be a structure that bonds components (for example, the first chip 110, the second chip 130, the bridge structure 140, the redistribution layer 170 and the chip stack 180) included in the semiconductor package 1 to each other.

According to some example embodiments, the semiconductor package 1 may include a first chip bonding layer 151. The first chip bonding layer 151 may be disposed on top of the first device layer 116. The first chip bonding layer 151 may be disposed on top of the first frontside 111. The first chip bonding layer 151 may include an insulating material.

According to some example embodiments, the semiconductor package 1 may include a second chip bonding layer 154. The second chip bonding layer 154 may be disposed between the first chip bonding layer 151 and the second device layer 136. The second chip bonding layer 154 may be disposed facing the first device layer 116. The second chip bonding layer 154 may include an insulating material.

According to some example embodiments, the first chip 110 may include the first chip pad 118. The first chip pad 118 may protrude from the first device layer 116. The first chip pad 118 may protrude from the first frontside 111. The first chip pad 118 may be located within the first chip bonding layer 151. The first chip pad 118 may be surrounded by the first chip bonding layer 151.

According to some example embodiments, the second chip 130 may include the second chip pad 138. The second chip pad 138 may protrude from the second device layer 136. The second chip pad 138 may protrude toward the first chip 110. The second chip pad 138 may be located within the second chip bonding layer 154. The second chip pad 138 may be surrounded by the second chip bonding layer 154.

According to some example embodiments, the first chip 110 and the second chip 130 may be bonded using the hybrid chip bonding (HCB) method. The first chip bonding layer 151 and the second chip bonding layer 154 may be disposed between the first device layer 116 and the second device layer 136. The first chip pad 118 electrically connected to the first semiconductor device 114 through the first wiring 113 may be located within the first chip bonding layer 151. The second chip pad 138 electrically connected to the second semiconductor device 134 through the second wiring 133 may be located within the second chip bonding layer 154. The first chip pad 118 may be in contact with the second chip pad 138 within the first chip bonding layer 151. The second chip pad 138 may make contact with the first chip pad 118 within the second chip bonding layer 154.

According to some example embodiments, the first chip 110 and the second chip 130 may be bonded in the face to face (F2F) method. The first device layer 116 of the first chip 110 and the second device layer 136 of the second chip 130 may face each other. The first chip pad 118 protruding from the first device layer 116 toward the second chip 130 and the second chip pad 138 protruding from the second device layer 136 toward the first chip 110 may be bonded to each other.

According to some example embodiments, the first chip 110 may include the bridge connection pad 119. The bridge connection pad 119 may protrude from the first device layer 116. The bridge connection pad 119 may protrude from the first frontside 111. The bridge connection pad 119 may be located within the first chip bonding layer 151. The bridge connection pad 119 may be surrounded by the first chip bonding layer 151.

According to some example embodiments, the semiconductor package 1 may include a first bridge bonding layer 152. The first bridge bonding layer 152 may be disposed between the through via 142 and the first chip 110. The first bridge bonding layer 152 may be disposed between the first chip bonding layer 151 and the through via 142. The first bridge bonding layer 152 may include an insulating material.

According to some example embodiments, the bridge structure 140 may include the first bridge pad 143. The first bridge pad 143 may be electrically connected to the through via 142. The first bridge pad 143 may be located within the first bridge bonding layer 152. The first bridge pad 143 may be surrounded by the first bridge bonding layer 152.

According to some example embodiments, the first chip 110 and the bridge structure 140 may be bonded using the HCB method. The first chip bonding layer 151 and the first bridge bonding layer 152 may be disposed between the first device layer 116 and the bridge structure 140. The bridge connection pad 119, which is electrically connected to the first semiconductor device 114 through the first wiring 113, may be located within the first chip bonding layer 151. The first bridge pad 143, which is electrically connected to the through via 142, may be located within the first bridge bonding layer 152. The bridge connection pad 119 may make contact with the first bridge pad 143 within the first chip bonding layer 151. The first bridge pad 143 may make contact with the bridge connection pad 119 within the first bridge bonding layer 152.

According to some example embodiments, the semiconductor package 1 may include the redistribution layer 170. The redistribution layer 170 may be disposed on top of the bridge structure 140. The redistribution layer 170 may be disposed on top of the second chip 130. The redistribution layer 170 may be electrically connected to the through via 142.

According to some example embodiments, the redistribution layer 170 may include a redistribution substrate 171. The redistribution substrate 171 may include a non-conductive material. The redistribution layer 170 may include a redistribution circuit 172. The redistribution circuit 172 may include a conductive material. The redistribution circuit 172 may be disposed inside the redistribution substrate 171.

According to some example embodiments, the redistribution layer 170 may include the first redistribution pad 173 and a second redistribution pad 174. The first redistribution pad 173 may electrically connect the redistribution circuit 172 and the through via 142. The first redistribution pad 173 may protrude from the redistribution substrate 171 toward the through via 142. The second redistribution pad 174 may electrically connect the redistribution circuit 172 and the chip stack 180. The second redistribution pad 174 may protrude from the redistribution substrate 171 toward the chip stack 180.

According to some example embodiments, the semiconductor package 1 may include a second bridge bonding layer 153. The second bridge bonding layer 153 may be disposed between the through via 142 and the redistribution layer 170. The second bridge bonding layer 153 may be disposed between a first redistribution bonding layer 155 and the through via 142. The second bridge bonding layer 153 may include an insulating material.

According to some example embodiments, the bridge structure 140 may include the second bridge pad 144. The second bridge pad 144 may be electrically connected to the through via 142. The second bridge pad 144 may be located within the second bridge bonding layer 153. The second bridge pad 144 may be surrounded by the second bridge bonding layer 153.

According to some example embodiments, the semiconductor package 1 may include the first redistribution bonding layer 155. The first redistribution bonding layer 155 may be disposed between the through via 142 and the redistribution layer 170. The first redistribution bonding layer 155 may be disposed between the second bridge bonding layer 153 and the redistribution substrate 171. The first redistribution bonding layer 155 may include an insulating material.

According to some example embodiments, the redistribution layer 170 and the bridge structure 140 may be bonded in the HCB method. The first redistribution bonding layer 155 and the second bridge bonding layer 153 may be disposed between the redistribution substrate 171 and the bridge structure 140. The first redistribution pad 173 electrically connected to the redistribution circuit 172 may be located within the first redistribution bonding layer 155. The second bridge pad 144 electrically connected to the through via 142 may be located within the second bridge bonding layer 153. The first redistribution pad 173 may make contact with the second bridge pad 144 within the first redistribution bonding layer 155. The second bridge pad 144 may make contact with the first redistribution pad 173 within the second bridge bonding layer 153.

According to some example embodiments, the semiconductor package 1 may include a first molding layer 161. The first molding layer 161 may surround the second chip 130. The first molding layer 161 may surround the bridge structure 140. The first molding layer 161 may contain an epoxy molding compound (EMC) material. The first molding layer 161 may be disposed between the first chip 110 and the redistribution layer 170.

According to some example embodiments, the first molding layer 161 may include a first molding part 1611. The second chip 130 may be separated from the redistribution layer 170. A gap (G) may be formed between the second chip 130 and the redistribution layer 170. The first molding part 1611 may be a portion of the first molding layer 161 located between the second chip 130 and the redistribution layer 170.

According to some example embodiments, the semiconductor package 1 may include the chip stack 180. The chip stack 180 may be high bandwidth memory (HBM). The chip stack 180 may include a plurality of third chips 182a, 182b and 182c stacked on top of each other. Each of the plurality of third chips 182a, 182b and 182c may be a DRAM. The chip stack 180 may be disposed on top of the redistribution layer 170. The chip stack 180 may be electrically connected to the redistribution layer 170 via solder bumps 181. A plurality of chip stacks 180 may be disposed spaced apart from each other in the third direction (+X).

According to some example embodiments, the semiconductor package 1 may include the third chip 182. The third chip 182 may be a DRAM. A plurality of third chips 182 may be stacked on top of each other to form the chip stack 180. The plurality of third chips 182 may be stacked on top of the redistribution layer 170. Each of the plurality of third chips 182 may be electrically connected to the redistribution layer 170.

According to some example embodiments, the third chip 182 may include the third substrate layer 1821. The third substrate layer 1821 may include a non-conductive material. The third substrate layer 1821 may include a third conductive via 1825. The third conductive via 1825 may extend through the third substrate layer 1821. The third conductive via 1825 may electrically connect a third chip pad 1826 and the third wiring 1824.

According to some example embodiments, the third chip 182 may include the third device layer 1822. The third device layer 1822 may include the third semiconductor device 1827 and the third wiring 1824 electrically connected to the third semiconductor device 1827.

According to some example embodiments, the chip stack 180 may include a chip stack bonding layer 1823. The chip stack bonding layer 1823 may be disposed between the plurality of third chips 182a, 182b and 182c. The third chip 182 may include the third chip pad 1826 protruding into the chip stack bonding layer 1823. The third conductive via 1825 may electrically connect the third chip pad 1826 and the third wiring 1824. The third chip pad 1826 of any one of the plurality of third chips 182a, 182b and 182c may be in contact with another adjacent third chip pad 1826 among the plurality of third chips 182a, 182b and 182c. The plurality of third chips 182a, 182b and 182c may be bonded to each other using the HCB method.

According to some example embodiments, the chip stack 180 may include a solder bump 181. The solder bump 181 may protrude toward the redistribution layer 170.

According to some example embodiments, the semiconductor package 1 may include a second redistribution bonding layer 156. The second redistribution bonding layer 156 may be disposed between the chip stack 180 and the redistribution layer 170. The second redistribution bonding layer 156 may be disposed between the solder bump 181 and the redistribution substrate 171. The second redistribution bonding layer 156 may include an insulating material.

According to some example embodiments, the redistribution layer 170 may include the second redistribution pad 174. The second redistribution pad 174 may protrude from the redistribution substrate 171 toward the chip stack 180. The second redistribution pad 174 may be located within the second redistribution bonding layer 156. The second redistribution pad 174 may be surrounded by the second redistribution bonding layer 156.

According to some example embodiments, the redistribution layer 170 and the chip stack 180 may be bonded using a flip-chip bonding method. The second redistribution bonding layer 156 may be disposed between the redistribution substrate 171 and the chip stack 180. The second redistribution pad 174 electrically connected to the redistribution circuit 172 may be located within the second redistribution bonding layer 156. The solder bump 181 electrically connected to the third semiconductor device 1827 of each of the plurality of third chips 182a, 182b and 182c may protrude toward the second redistribution bonding layer 156, through the third wiring 1824 of each of the plurality of third chips 182a, 182b and 182c. The second redistribution pad 174 may make contact with the solder bump 181 within the second redistribution bonding layer 156.

According to some example embodiments, the semiconductor package 1 may include the molding layer 160. The molding layer 160 may surround components included in the semiconductor package 1 (for example, the second chip 130, the bridge structure 140 and the chip stack 180). The molding layer 160 may include the first molding layer 161 surrounding the second chip 130 and the bridge structure 140.

According to some example embodiments, the semiconductor package 1 may include a second molding layer 162. The second molding layer 162 may surround the chip stack 180. The second molding layer 162 may contain an EMC material. The second molding layer 162 may be disposed on top of the redistribution layer 170.

According to an embodiment of the present disclosure, the semiconductor package 1 may have the second chip 130, which is a memory chip, bonded over the first chip 110, which is a logic chip, in a F2F manner, and the power distribution layer 120 for power supply may be disposed under the first chip 110. For power transmission from the power distribution layer 120 located under the first chip 110 to the chip stack 180, the semiconductor package 1 according to an embodiment of the present disclosure may place the through via 142 over the first chip 110 and place the redistribution layer 170 on the upper side of the through via 142 to supply power to each of the plurality of third chips 182a, 182b and 182c included in the chip stack 180 through the through via 142 and the redistribution layer 170.

The semiconductor package 1 according to an embodiment of the present disclosure may reduce signal latency in signal transmission between chips (for example, the first chip 110 and the second chip 130). For example, in the semiconductor package 1 according to an embodiment of the present disclosure, by the first chip 110 and the second chip 130 being bonded in the F2F manner, the signal latency may be reduced by reducing the distance between the first device layer 116 and the second device layer 136.

In the semiconductor package 1 according to an embodiment of the present disclosure, power supply to the chip stack 180 may be smooth. For example, in the semiconductor package 1 according to an embodiment of the present disclosure, by placing the through via 142 over the first chip 110 and placing the redistribution layer 170 between the through via 142 and the chip stack 180, the power generated in the power distribution layer 120 may be delivered to the first chip 110, the through via 142, and to the plurality of third chips 182 a, 182 b and 182 c of the chip stack 180 through the redistribution layer 170.

In the semiconductor package 1 according to an embodiment of the present disclosure, the heat transferred to each chip (for example, the first chip 110, the second chip 130 and the third chip 182) may be reduced. The heat transferred to each chip (the first chip 110, the second chip 130 and the third chip 182) may degrade the performance of each chip (the first chip 110, the second chip 130 and the third chip 182). In the semiconductor package 1 according to an embodiment of the present disclosure, by releasing heat through the through via 142 that has high thermal conductivity, the amount of heat transferred to each chip (the first chip 110, the second chip 130 and the third chip 182) may be reduced. For example, the first thermal conductivity of the through via 142 may be greater than the second thermal conductivity of the molding layer 160. The through via 142 may function as a heat sink.

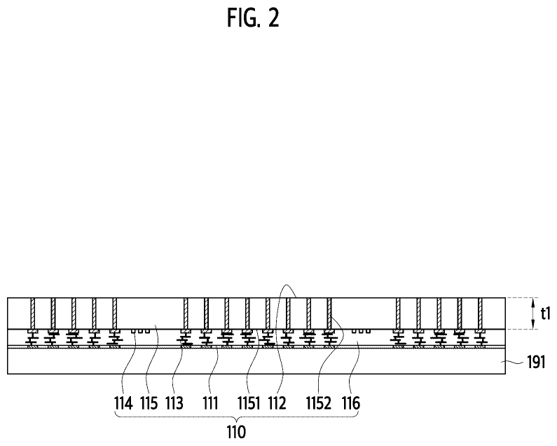

FIG. 2 to FIG. 12 are drawings explaining a method for manufacturing the semiconductor package 1 according to an embodiment of the present disclosure. With respect to description of components described with reference to FIG. 2 to FIG. 12, the description of the components described with reference to FIG. 1 may be applied equally.

Referring to FIG. 2, the first chip 110 may be disposed on a first carrier substrate 191. The first chip 110 may be disposed on the first carrier substrate 191 such that the first device layer 116 faces the first carrier substrate 191. The first frontside 111 may face the first carrier substrate 191. The first backside 112 may be located away from the first carrier substrate 191 than the first frontside 111. The first substrate layer 115 may have a first thickness t1. The first conductive via 1152 arranged within the first substrate layer 115 may extend to a length corresponding to the first thickness t1 of the first substrate layer 115.

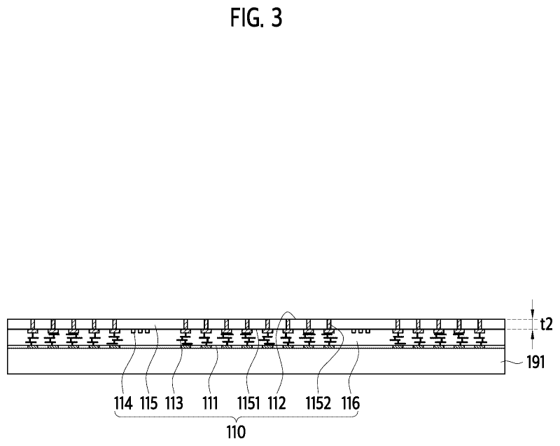

Referring to FIG. 3, the first substrate layer 115 may have a second thickness t2 that is smaller than the first thickness (for example, the first thickness t1 in FIG. 2). The first substrate layer 115 illustrated in FIG. 2 may be partially polished together with the first conductive via 1152. The first conductive via 1152 may be cut to a length corresponding to the second thickness t2 of the first substrate layer 115.

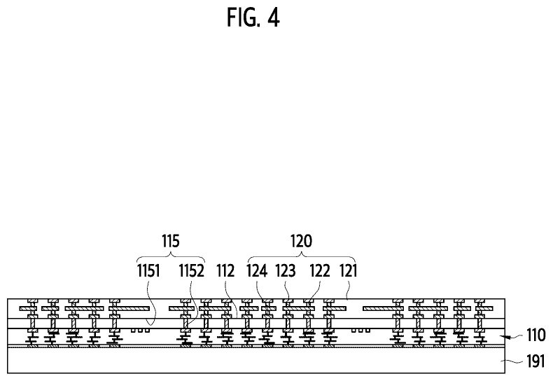

Referring to FIG. 4, the power distribution layer 120 may be disposed on top of the first chip 110. The power wiring insulating film 121 may be disposed on the first substrate layer 115. The power distribution layer 120 may be disposed facing the first backside 112 of the first chip 110. The power wiring 122 inside the power wiring insulating film 121 may be electrically connected to the first conductive via 1152 through the second power wiring pad 124.

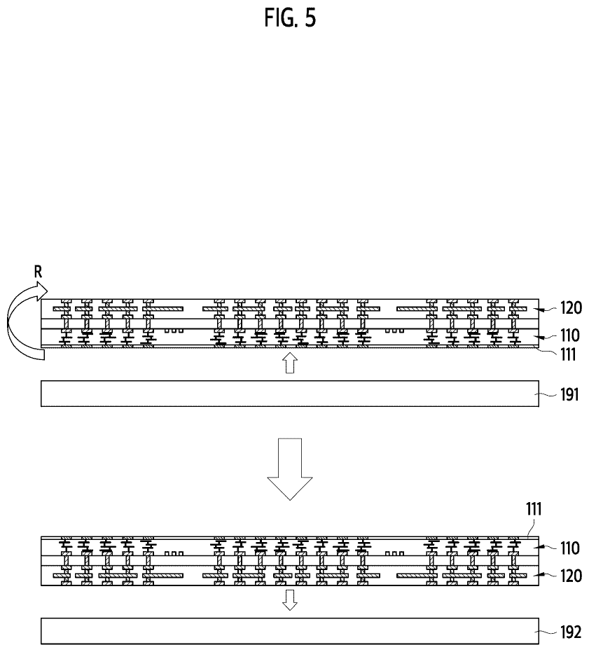

Referring to FIG. 5, the first chip 110 and the power distribution layer 120 may be separated from the first carrier substrate 191. The first chip 110 and the power distribution layer 120 may be separated from the first carrier substrate 191 with the first frontside 111 facing the first carrier substrate 191. After being separated from the first carrier substrate 191, the first chip 110 and the power distribution layer 120 may be rotated in the rotational direction (R) and flipped over. After being rotated in the rotation direction (R) and then flipped over, the first chip 110 and the power distribution layer 120 may be stacked on a second carrier substrate 192. Here, the power distribution layer 120 may face the second carrier substrate 192. The first chip 110 may be located further from the second carrier substrate 192 than the power distribution layer 120. The first frontside 111 may be located away from the second carrier substrate 192 than the power distribution layer 120. The first chip 110 and the power distribution layer 120 may be transferred from the first carrier substrate 191 to the second carrier substrate 192.

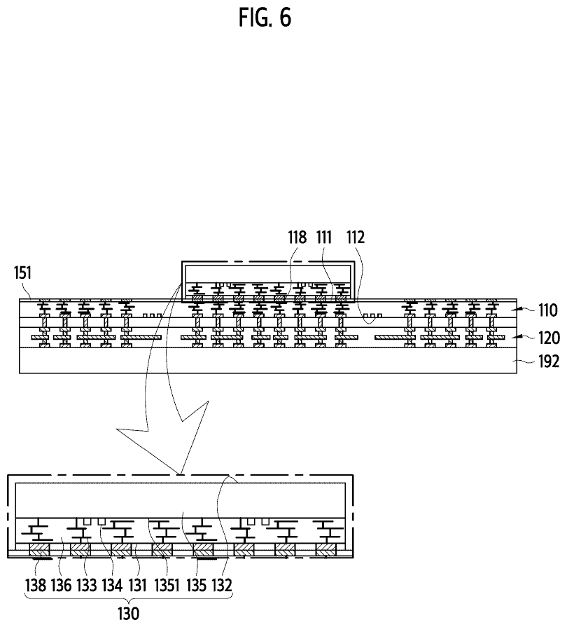

Referring to FIG. 6, the second chip 130 may be stacked on top of the first chip 110. The second chip 130 may be stacked on the first chip 110 with the second device layer 136 positioned facing the first chip 110. The second frontside 131 may face the first frontside 111. The first chip bonding layer 151 may be disposed between the first frontside 111 and the second chip 130. The first chip 110 and the second chip 130 may be bonded in the HCB method. The first chip pad 118 and the second chip pad 138 may be in contact with each other.

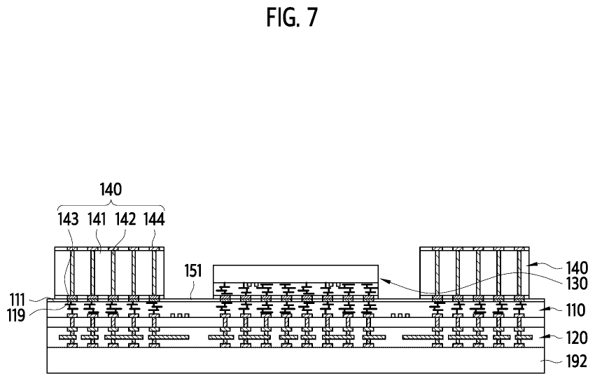

Referring to FIG. 7, the bridge structure 140 may be stacked on the upper side of the first chip 110. The bridge structure 140 may be stacked on top of the first chip 110 at a location spaced from the lateral side (e.g., a peripheral side) of the second chip 130. The first chip bonding layer 151 may be disposed between the first chip 110 and the bridge structure 140. The bridge structure 140 and the first chip 110 may be bonded in the HCB method. The through via 142 may be electrically connected to the first chip 110 through the first bridge pad 143. The first bridge pad 143 may be contacted with the bridge connection pad 119.

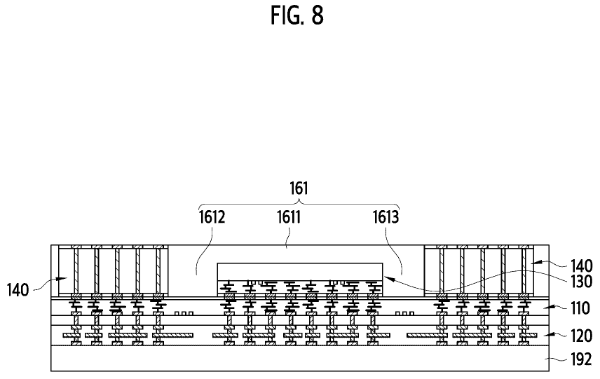

Referring to FIG. 8, the first molding layer 161 may be formed surrounding the second chip 130 and the bridge structure 140. The first molding layer 161 may contain an EMC material. The first molding layer 161 may include the first molding part 1611 positioned over the second chip 130. The first molding layer 161 may include a second molding part 1612 and a third molding part 1613 positioned between the second chip 130 and the bridge structure 140.

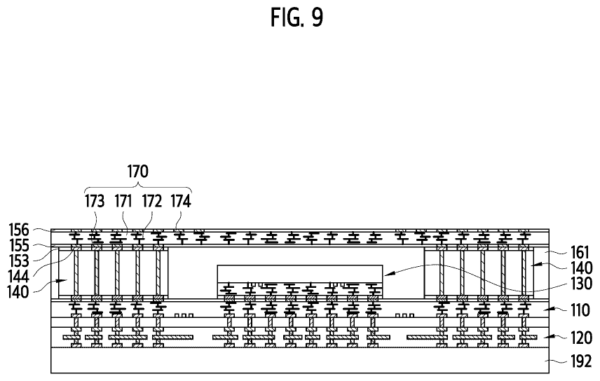

Referring to FIG. 9, the redistribution layer 170 may be laminated on the upper side of the bridge structure 140. The redistribution layer 170 may be disposed on top of the first molding layer 161. The redistribution layer 170 may be electrically connected to the through via 142. The redistribution layer 170 and the bridge structure 140 may be bonded in the HCB method. The second bridge bonding layer 153 and the first redistribution bonding layer 155 may be disposed between the redistribution layer 170 and the through via 142. The through via 142 may be electrically connected to the redistribution circuit 172 through the second bridge pad 144. The second bridge pad 144 may be contacted with the first redistribution pad 173.

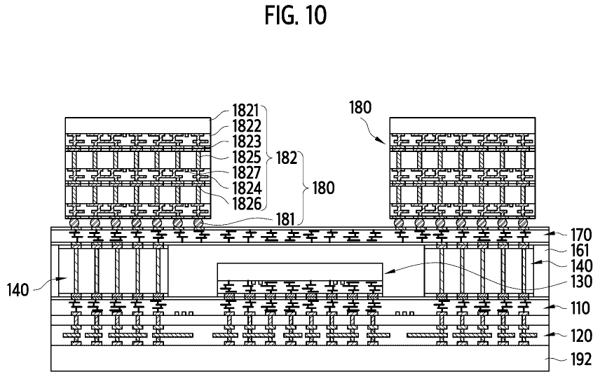

Referring to FIG. 10, the chip stack 180 may be stacked on top of the redistribution layer 170. The solder bump 181 may be disposed on top of the redistribution layer 170. The third chip 182 included in the chip stack 180 may be electrically connected to the redistribution layer 170. The third semiconductor device 1827 included in the third chip 182 may be electrically connected to the redistribution layer 170 through the third wiring 1824 and the solder bump 181. The chip stack 180 and the redistribution layer 170 may be bonded by flip-chip bonding method. The second redistribution bonding layer 156 may be disposed between the chip stack 180 and the redistribution layer 170. The second redistribution pad 174 may come into contact with the solder bump 181.

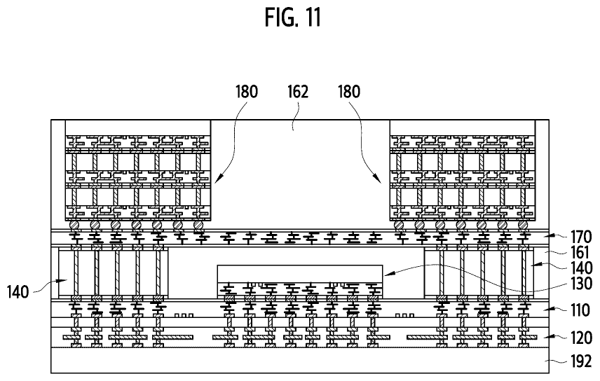

Referring to FIG. 11, the second molding layer 162 may be formed surrounding the chip stack 180. The second molding layer 162 may contain an EMC material. The second molding layer 162 may be disposed on top of the redistribution layer 170.

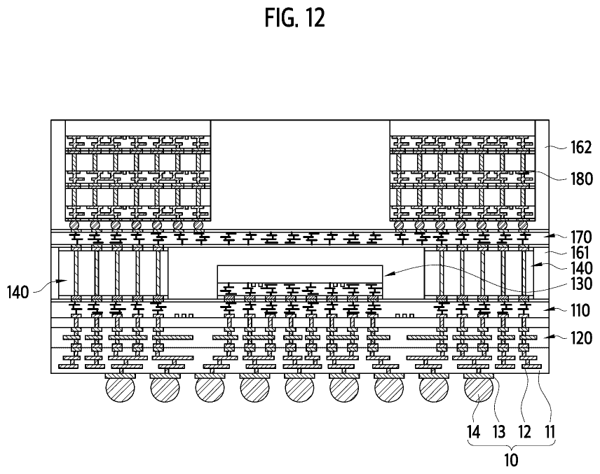

Referring to FIG. 12, the second carrier substrate 192 (of FIG. 11) may be removed and the package substrate 10 may be formed under the power distribution layer 120. The redistribution structure 12 of the package substrate 10 may be electrically connected to the power distribution layer 120.

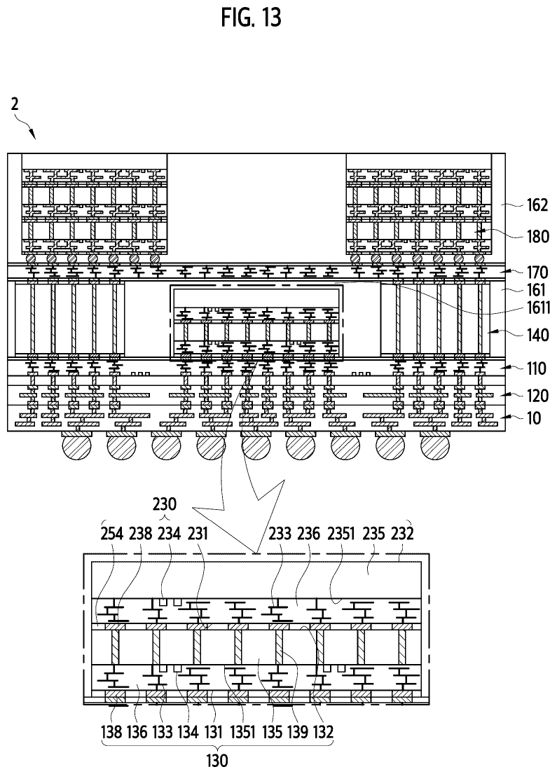

FIG. 13 is a drawing of a semiconductor package 2 according to another embodiment of the present disclosure. With respect to description of components described with reference to FIG. 13, the description of the components described with reference to FIG. 1 to FIG. 12 may be equally applied. For example, the semiconductor package 2 may include the package substrate 10, the first chip 110, the power distribution layer 120, the second chip 130, the bridge structure 140, the first molding layer 161, the first molding part 1611, the redistribution layer 170, the chip stack 180 and the second molding layer 162.

According to some example embodiments, the semiconductor package 2 may include a fourth chip 230. The fourth chip 230 may be disposed between the second chip 130 and the redistribution layer 170. The first molding layer 161 may include the first molding part 1611 positioned between the second chip 130 and the redistribution layer 170. The fourth chip 230 may be positioned corresponding to the first molding part 1611.

According to some example embodiments, the fourth chip 230 may be a memory chip. For example, the fourth chip 230 may be the LLC DRAM. The fourth chip 230 may be disposed on the upper side of the package substrate 10. The fourth chip 230 may be disposed on top of the second chip 130. The fourth chip 230 may be electrically connected to the second chip 130. The fourth chip 230 may receive power from the power distribution layer 120 through the second chip 130.

According to some example embodiments, the fourth chip 230 may include a fourth frontside 231 and a fourth backside 232. The fourth frontside 231 may be arranged to face the second chip 130. The fourth backside 232 may be disposed facing the redistribution layer 170. The fourth backside 232 may be a side of the fourth chip 230 opposite to the fourth frontside 231. The fourth backside 232 may be located further from the second chip 130 than the fourth frontside 231.

According to some example embodiments, the fourth chip 230 may be arranged such that the fourth frontside 231 faces the second chip 130. The fourth frontside 231 may face the second backside 132. A fourth device layer 236 of the fourth chip 230 may face the second substrate layer 135 of the second chip 130.

According to some example embodiments, the fourth chip 230 may include a fourth substrate layer 235. The fourth substrate layer 235 may include a non-conductive material (for example, silicon (Si)). The fourth substrate layer 235 may include the fourth backside 232. The fourth substrate layer 235 may include a fourth substrate surface 2351. The fourth substrate surface 2351 may be a side of the fourth substrate layer 235 that is opposite to the fourth backside 232. The fourth substrate surface 2351 may face the fourth device layer 236.

According to some example embodiments, the fourth chip 230 may include the fourth device layer 236. The fourth device layer 236 may include the fourth frontside 231. The fourth frontside 231 may be a side of the fourth device layer 236 that faces opposite to the direction toward the fourth substrate layer 235.

According to some example embodiments, the fourth chip 230 may include a fourth semiconductor device 234. The fourth semiconductor device 234 may be disposed within the fourth device layer 236. The fourth semiconductor device 234 may be disposed on the fourth substrate surface 2351.

According to some example embodiments, the fourth chip 230 may include a fourth wiring 233. The fourth wiring 233 may be disposed inside the fourth device layer 236. The fourth wiring 233 may be electrically connected to the fourth semiconductor device 234. The fourth wiring 233 may contain a conductive material, and transmit electrical signals generated from the fourth semiconductor device 234. The fourth wiring 233 may be extended towards the fourth frontside 231, and be connected to a fourth chip pad 238 located at the fourth frontside 231.

According to some example embodiments, the second chip 130 may include a second conductive via 139 disposed within the second substrate layer 135. The second conductive via 139 may extend from the second substrate surface 1351 toward the second backside 132. The second conductive via 139 may be electrically connected to the fourth chip 230.

According to some example embodiments, the fourth chip 230 may include the fourth chip pad 238. The fourth chip pad 238 may face the second chip 130. The fourth chip pad 238 may protrude from the fourth frontside 231 toward the second backside 132. The fourth chip pad 238 may be contacted with the second conductive via 139. The fourth chip pad 238 may electrically connect the fourth wiring 233 and the second conductive via 139. The second conductive via 139 may electrically connect the fourth chip pad 238 and the second wiring 133. The fourth chip 230 may receive power and signals from the second chip 130 via the second conductive via 139.

According to example embodiments, it is possible for a semiconductor package to supply power to chips smoothly.

According to example embodiments, it is possible for a semiconductor package to reduce signal transmission latency between chips.

According to example embodiments, it is possible to improve heat dissipation efficiency with a semiconductor package.

In the above, various embodiments of the present disclosure are described in detail but, it will be apparent to those with average knowledge in the technical field that scope of rights of this disclosure is not limited thereto, and various modifications and variations are possible without departing from the technical spirit of the present disclosure as set forth in the claims. Further, the above-described example embodiments may be implemented with some elements deleted, and each example embodiment may be implemented in combination with each other.

What is claimed is:

1. A semiconductor package comprising:
a first chip comprising a first substrate layer disposed above a power distribution layer, and a first device layer that includes a first semiconductor device and is disposed over the first substrate layer;
a second chip comprising a second device layer that includes a second semiconductor device and is disposed over the first chip to face the first device layer, and a second substrate layer disposed over the second device layer;
a third chip disposed over the first chip, and disposed farther from the first chip than the second chip in a first direction;
a redistribution layer disposed between the second chip and the third chip, and electrically connected to the third chip; and
a through via spaced apart from the second chip, disposed between the redistribution layer and the first chip, and electrically connecting the redistribution layer and the first chip.

2. The semiconductor package of claim 1, wherein the first chip comprises a first conductive via penetrating the first substrate layer, and electrically connecting the power distribution layer and the first semiconductor device.

3. The semiconductor package of claim 1, further comprising:
a first chip bonding layer disposed between the first device layer and the through via;
a first bridge bonding layer disposed between the first chip bonding layer and the through via;
a bridge connection pad electrically connected to the first semiconductor device, and positioned in the first chip bonding layer; and
a first bridge pad contacting the bridge connection pad in the first bridge bonding layer, and electrically connecting the through via and the bridge connection pad.

4. The semiconductor package of claim 1, further comprising:
a first chip bonding layer disposed between the first device layer and the second device layer;
a second chip bonding layer disposed between the first chip bonding layer and the second device layer;
a first chip pad electrically connected to the first semiconductor device, and positioned in the first chip bonding layer; and
a second chip pad in the second chip bonding layer, contacting the first chip pad, and electrically connecting the second semiconductor device and the first chip pad.

5. The semiconductor package of claim 1, further comprising a first molding layer surrounding the through via and the second chip,
wherein the first molding layer comprises a first molding part positioned in a spaced portion between the second chip and the redistribution layer.

6. The semiconductor package of claim 1, further comprising a fourth chip disposed between the second chip and the redistribution layer,
wherein the fourth chip comprises a fourth device layer that includes a fourth semiconductor device and facing the second substrate layer, and
wherein the second chip comprises a second conductive via penetrating the second substrate layer and connecting the second device layer and the fourth device layer.

7. The semiconductor package of claim 1, further comprising a bridge structure comprising the through via and a bridge substrate surrounding the through via,
wherein the bridge structure comprises:
a first bridge structure; and
a second bridge structure spaced apart from the first bridge structure, wherein the second chip is positioned between the first bridge structure and the second bridge structure.

8. The semiconductor package of claim 1, wherein the third chip is a chip stack comprising a plurality of chips stacked with each other, and
wherein the power distribution layer is configured to supply power to the chip stack.

9. The semiconductor package of claim 1, further comprising a package substrate disposed under the power distribution layer, and including a redistribution structure connected to the power distribution layer.

10. The semiconductor package of claim 1, further comprising a first molding layer surrounding the through via and the second chip,
wherein a first thermal conductivity of the through via is greater than a second thermal conductivity of the first molding layer.

11. A semiconductor package comprising:
a first chip comprising a first substrate layer disposed above a power distribution layer, and a first device layer that includes a first semiconductor device and is disposed over the first substrate layer;
a second chip comprising a second substrate layer and a second device layer that includes a second semiconductor device and is disposed over the first chip;
a redistribution layer disposed over the second chip, and spaced apart from the first chip; and
a through via spaced apart from the second chip, disposed between the redistribution layer and the first chip, and electrically connecting the redistribution layer and the first chip.

12. The semiconductor package of claim 11, further comprising a third chip disposed over the redistribution layer, and electrically connected to the through via through the redistribution layer.

13. The semiconductor package of claim 11, wherein the through via is positioned between the first chip and a portion of the redistribution layer, and
wherein the second chip is positioned between the first chip and another portion of the redistribution layer.

14. The semiconductor package of claim 11, further comprising a fourth chip disposed between the second chip and the redistribution layer.

15. The semiconductor package of claim 11, further comprising a package substrate disposed under the first chip,
wherein the power distribution layer is disposed between the package substrate and the first substrate layer.

16. A method of manufacturing a semiconductor package, the method comprising:
disposing a power distribution layer over a first side of a first chip, wherein the first chip comprises a first device layer including a first semiconductor device;
disposing a second chip over a second side of the first chip, wherein the second chip comprises a second device layer including a second semiconductor device, and the second device layer faces the first device layer;
disposing a through via over the first chip at a lateral side of the second chip;
disposing a redistribution layer over the through via, wherein the redistribution layer is electrically connected to the through via; and
disposing a third chip over the redistribution layer, wherein the third chip is electrically connected to the redistribution layer.

17. The method of claim 16, further comprising contacting a bridge connection pad protruding from the first device layer toward the through via and a first bridge pad protruding from the through via toward the first device layer.

18. The method of claim 16, further comprising contacting a first chip pad protruding from the first device layer toward the second device layer and a second chip pad protruding from the second device layer toward the first device layer.

19. The method of claim 16, further comprising:
disposing a fourth chip over the second chip; and
disposing the redistribution layer over the second chip and the fourth chip.

20. The method of claim 16, further comprising:
disposing a package substrate comprising a redistribution structure under the power distribution layer.
